(19) United States
(12) Patent Application Publication
(10) Pub. No.: US 2020/0403102 A1
(43) Pub. Date: Dec. 24, 2020

(54) ELECTRODE STRUCTURE AND MANUFACTURING METHOD THEREOF, THIN FILM TRANSISTOR, AND ARRAY SUBSTRATE

(71) Applicant: BOE TECHNOLOGY GROUP CO., LTD., BEIJING (CN)

(72) Inventors: Dongfang WANG, Beijing (CN); Guangcai YUAN, Beijing (CN)

(21) Appl. No.: 16/326,256

(22) PCT Filed: Jun. 1, 2018
(86) PCT No.: PCT/CN2018/089632

§ 371 Date: Feb. 18, 2019

(30) Foreign Application Priority Data
Aug. 30, 2017 (CN) 201710769888.9
Aug. 30, 2017 (CN) 201721104937.9

(51) Int. Cl. H01L 29/786; H01L 29/40; H01L 29/49; H01L 29/45

(52) U.S. Cl. CPC H01L 29/78606; H01L 29/401; H01L 27/124; H01L 29/458; H01L 29/45; H01L 29/4908

(57) ABSTRACT

Embodiments of the present invention disclose an electrode structure, a method of fabricating the same, a thin film transistor, and an array substrate. An electrode structure is provided that comprises: an electrical conductor (23 or 25) including a protective layer and a conductive layer (10), the protective layer comprising: a first protective layer (11 and 12) disposed on a surface of the conductive layer and a second protective layer (13) disposed on at least a side face of the conductive layer, the second protective layer being configured for isolating the conductive layer from the outside.

### CROSS-REFERENCE TO RELATED APPLICATIONS

The present application claims priority to the Chinese Application No. 201710769888.9 filed on Aug. 30, 2017 and the Chinese Application No. 201721104937.9 filed on Aug. 30, 2017, which are herein incorporated in its entirety by reference.

### FIELD

Embodiments of the present disclosure relate to the field of display technologies, and in particular, to an electrode structure and a method for fabricating the same, a thin film transistor, and an array substrate.

### BACKGROUND

With the continuous development of Thin Film Transistor (TFT) liquid crystal display technology, TFT display devices with low power consumption, high resolution, fast response speed and high aperture ratio have gradually become mainstream, and have been widely used in various electronic devices such as LCD TVs, smartphones, tablets, and digital electronic devices. The thin film transistor TFT may include an active layer, a gate insulating layer, a gate electrode, an interlayer insulating layer, source/drain electrodes, and a passivation layer.

However, in a high-temperature and high-humidity environment, bubbles or even cracks are prone to be generated in the surface of the electrode structure, thereby affecting the conductivity and lowering the yield of the thin film transistor.

### SUMMARY

According to an aspect of the present disclosure, an electrode structure is provided that comprises: a conductor including a protective layer and a conductive layer; wherein the protective layer comprises: a first protective layer disposed on a surface of the conductive layer, and a second protective layer disposed on a side face of the conductive layer for isolating the conductive layer from the outside.

In an embodiment, materials of the first protective layer and the second protective layer are different. In an embodiment, the second protective layer is configured to block oxygen and/or hydrogen.

In an embodiment, the first protective layer comprises a first metal layer and a second metal layer, the first metal layer being disposed on a side of the conductive layer adjacent to a substrate, the second metal layer is disposed on a side of the conductive layer facing away from the substrate.

In an embodiment, the second protective layer is configured to cover the side face of the conductive layer, and the height of the second protective layer is the same as the thickness of the conductive layer. In an embodiment, the second protective layer is configured to completely cover the side face of the conductive layer.

In an embodiment, the second protective layer is configured to cover sides of the first metal layer, the conductive layer, and the second metal layer, the height of the second protective layer is substantially equal to a sum of the thicknesses of the first metal layer, the conductive layer, and the second metal layer.

In an embodiment, material of the conductive layer comprises aluminum, and material of the second protective layer comprises aluminum nitride. In an embodiment, materials of the first metal layer and the second metal layer are different.

In an embodiment, the second protective layer has a thickness of 5 to 50 nm.

In an embodiment, materials of the first metal layer and the second metal layer comprise: molybdenum (Mo).

In an embodiment, the conductive layer comprises a metal material.

According to another aspect of the present disclosure, a thin film transistor is provided that comprises an electrode structure according to any embodiments, wherein the conductor is at least one of the following: gate electrode, source electrode, drain electrode, or wiring of the thin film transistor.

According to a further aspect of the present disclosure, an array substrate is provided that comprises the thin film transistor of any aspect or embodiment.

According to a still further aspect of the present disclosure, a method for fabricating an electrode structure is provided, comprising: forming a conductive layer on a substrate and a first protective layer for the conductive layer; and forming a second protective layer covering at least a side of the conductive layer for isolating the conductive layer from the outside.

In an embodiment, materials of the first protective layer and the second protective layer are different. In an embodiment, the second protective layer is configured to block oxygen and/or hydrogen.

In an embodiment, forming the conductive layer on the substrate and the first protective layer on a surface of the conductive layer comprises: forming a stack of a first metal film, a conductive film, and a second metal film on the substrate; patterning the stack to form a first metal layer, the conductive layer, and a second metal layer, wherein the first protective layer comprises the first metal layer and the second metal layer.

In an embodiment, forming the second protective layer comprises: processing the conductive layer with nitrogen plasma to form the second protective layer.

In an embodiment, forming the second protective layer comprises: depositing a protective material film on the substrate on which the first metal layer, the conductive layer and the second metal layer are formed, the protective material film covering at least the second metal layer and sides of the first metal layer, the conductive layer and the second metal layer; and remaining a portion of the protective material film which is on the sides of the first metal layer, the conductive layer, and the second metal layer by a patterning process to form the second protective layer.

In an embodiment, the conductor is at least one of the following: a gate electrode, a source electrode, a drain electrode, or a wiring of a thin film transistor.

In an embodiment, the conductive film is formed of metal material.

### BRIEF DESCRIPTION OF DRAWINGS

The drawings, which provide a further understanding of the technical solutions of the present disclosure and constitute a part of the specification, together with the embodiments of the present application, are used to explain the technical solutions of the present disclosure, and are not intended to limit the technical solutions of the present disclosure.

FIG. 1 is a simplified schematic diagram of a conventional thin film transistor;

FIG. 2 is a schematic structural diagram of an electrode according to some embodiments of the present disclosure;

FIG. 3 is a schematic structural diagram of a thin film transistor according to some embodiments of the present disclosure;

FIG. 4 is a schematic structural diagram of an electrode according to some embodiments of the present disclosure;

FIG. 5 is a schematic structural diagram of a thin film transistor according to some embodiments of the present disclosure;

FIG. 6 is a flow chart of a method of fabricating a thin film transistor according to some embodiments of the present disclosure;

FIG. 6A is a schematic diagram of a method of fabricating a thin film transistor according to some embodiments of the present disclosure;

FIG. 6B is a schematic diagram of a method of fabricating a thin film transistor according to some embodiments of the present disclosure;

FIG. 6C is a schematic diagram of a method of fabricating a thin film transistor according to some embodiments of the present disclosure;

FIG. 6D is a schematic diagram of a method of fabricating a thin film transistor according to some embodiments of the present disclosure;

FIG. 7A is a schematic diagram of a method of fabricating a thin film transistor according to some embodiments of the present disclosure; and

FIG. 7B is a schematic diagram of a method of fabricating a thin film transistor according to some embodiments of the present disclosure.

### DETAILED DESCRIPTION

In order to make the objects, technical solutions and advantages of the present disclosure more clear, the embodiments of the present disclosure will be described in detail below with reference to the accompanying drawings. It should be noted that, in the case of no conflict, the embodiments in the present application, as well as the features in the embodiments, may be freely combined with each other.

For the sake of clarity, the thicknesses and sizes of the layers or microstructures are exaggerated in the figures which describe embodiments of the present disclosure. It is to be understood that when an element, such as a layer, a film, a region or a substrate, is referred to as being “on” or “under” another element, that element can be “on” or “under” said another element directly, or there may be intermediate element therebetween.

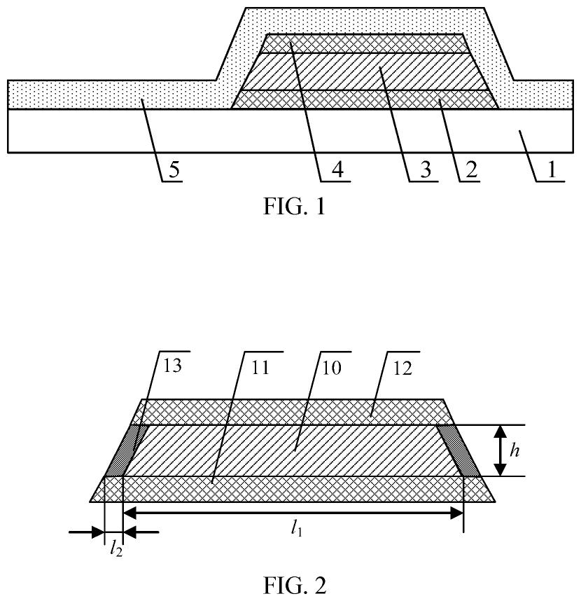

FIG. 1 is a simplified schematic diagram of a conventional thin film transistor. As shown in FIG. 1, an electrode is formed on the substrate 1, and an insulating layer 5 made of silicon oxide is disposed on the electrode. The electrode comprises: a first layer 2 of molybdenum material, a second layer 3 of aluminum material and a third layer 4 of molybdenum material. The electrode is a gate electrode or a source/drain electrode. When the electrode is a gate electrode, the insulating layer may be an interlayer insulating layer in a top gate structure, whereas the insulating layer may be a gate insulating layer in a bottom gate structure. When the electrode is a source/drain electrode, the insulating layer may be a passivation layer. In the fabrication process in practice, the edge portion of the second layer 3 may be oxidized to form aluminum oxide before or during the formation of the insulating layer 5. Therefore, after the insulating layer 5 is formed, the alumina at the edge of the second layer 3 is brought into contact with the silicon oxide.

The inventors have found that after the thin film transistor is fabricated, it is usually required to be placed in a high-temperature and high-humidity environment for reliability evaluation. On one hand, hydrogen atoms may always be present in the silicon oxide in a high temperature and high humidity environment. On the other hand, it is possible to introduce hydrogen-containing impurities such as water vapor by various manufacturing processes. Since the atomic gap of alumina is relatively large, the hydrogen atoms may “walk around” arbitrarily, breaking the bond between the metal aluminum and the alumina (aluminum oxide), so that a part of the aluminum atoms can move freely, thereby forming a lot of pits on the side of the metal aluminum. As the pit continues growing, the “walking” hydrogen atoms may have enough space to form hydrogen molecules and result in pressure on the surface of the metal aluminum. When the diameter of the pit is large to a certain critical size, the surface of the metal aluminum may be plastically deformed and bulged outward to form bubbles. When the density of the bubble is sufficiently large, the surface of the metal aluminum forming the bubble may be broken, resulting in uneven contact resistance of the second layer or even breakage of the metal the second layer, which seriously affects the conductivity of the electrode and reduces the yield of the thin film transistor. In addition, when the bubble density is sufficiently large, the oxide film protective layer on the electrode may fall off, eventually leading to failure.

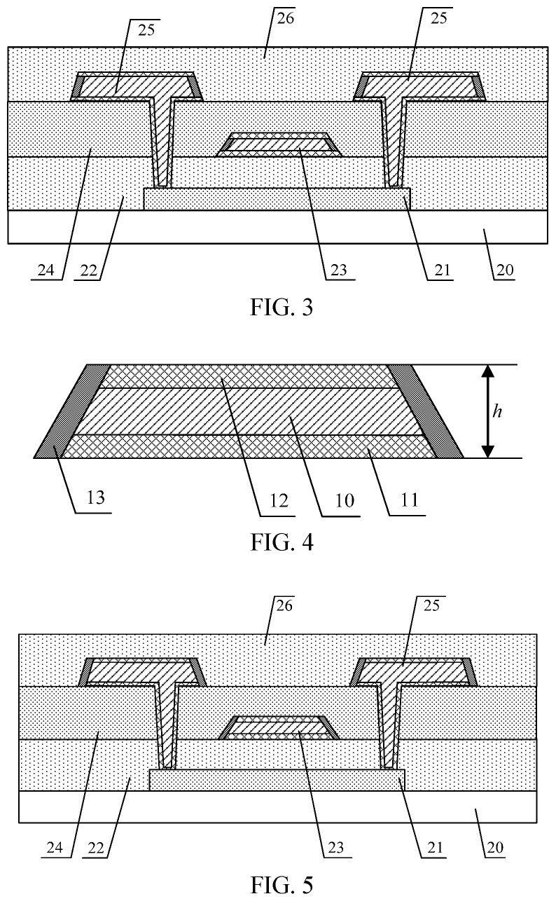

FIG. 2 is a schematic structural diagram of an electrode according to some embodiments of the present disclosure; FIG. 3 is a schematic structural diagram of a thin film transistor according to some embodiments of the present disclosure. As shown in FIGS. 2 and 3, the thin film transistor includes: a gate electrode 23 and source/drain electrodes 25. The gate electrode 23 and/or the source/drain electrodes 25 are electrodes including a protective layer and a conductive layer 10. The protective layer includes: first protective layers (11 and 12) disposed on the surfaces of the conductive layer 10 and a second protective layer 13 disposed on the side face of the conductive layer 10, the second protective layer 13 for isolating the conductive layer from the outside. For example, as shown in the figure, the second protective layer 13 can block the conductive layer from the silicon oxide.

In the present embodiment, the thin film transistor further includes: an active layer 21, a gate insulating layer 22, an interlayer insulating layer 24, and a passivation layer 26 disposed on the substrate 20, as shown in FIG. 3. It is to be noted that the structure of the thin film transistor may be a top gate structure or a bottom gate structure. FIG. 3 is an example of a top gate structure. In addition, FIG. 3 also illustrates an example in which the gate electrode and the source and drain electrodes are all electrode structures provided by the embodiments of the present disclosure. It should also be understood herein that the principles of embodiments of the present disclosure may be applied to a wide variety of devices comprising, but not limited to, semiconductor devices, such as active devices such as transistors, inactive devices, and the like. In addition, although the description has been made here with an example in which an electrode is employed as an example of conductor, it is obvious that the disclosure is not limited thereto. For example, in other embodiments, the principles of embodiments of the present disclosure may be adaptively or likewise applied to conductors such as wirings, pads, or the like.

In a specific implementation, the first protective layer includes: a first metal layer 11 disposed on the lower surface of the conductive layer 10 adjacent to the substrate 20, and a second metal layer 12 disposed on the upper surface of the conductive layer 10 facing away from the substrate 20. It is to be understood that, in some embodiments, as shown in the figures, the orthographic projection of the first metal layer 11 on the substrate 20 is greater than or equal to the orthographic projection of the conductive layer 10 on the substrate 20, and the orthographic projection of the conductive layer 10 on the substrate 20 is greater than or equal to the orthographic projection of the second metal layer 12 on the substrate 20. The shape of the conductive layer 10 may be a prismatic or prismatic structure, or may also be a truncated cone or a cylindrical structure. The shapes of the first metal layer 11 and the second metal layer 12 are the same as that of the conductive layer 10. Embodiments of the present disclosure shall not be limited to the embodiments shown or described herein.

The second protective layer 13 is disposed on the side of the conductive layer 10, and the height h of the second protective layer 13 is equal to the thickness of the conductive layer 10. It is to be understood that, in some embodiments, the sum of two times of the length 11 of the lower surface of the second protective layer 13, which is adjacent o the substrate 20, and the length 12 of the lower surface of the conductive layer 10, which is adjacent o the substrate 10, is less than or equal to the length of the upper surface of the first metal layer 11, which is facing away from the substrate 20. It is obvious that the present disclosure is not limited thereto. In some embodiments, the materials of the first protective layer and the second protective layer are different. Additionally, in some embodiments, the second protective layer can be disposed to completely cover the side of the conductive layer.

Optionally, the materials of the first metal layer 11 and the second metal layer 12 comprise molybdenum. It should be noted that the first metal layer 11 and the second metal layer 12 not only can be electrically conductive, but also can protect the conductive layer 10 from being oxidized. In some embodiments, the materials of the first metal layer and the second metal layer may be different.

The conductive layer 10 may be formed of metal material. Optionally, the material of the conductive layer 10 comprises: aluminum.

Optionally, the material of the second protective layer 13 comprises: aluminum nitride. It should be noted that the second protective layer 13 may also be other materials having weak hydrogen permeability. The present disclosure shall not be limited to the embodiments shown or described herein.

In a specific implementation, the shape of the second protective layer 13 is related to the shape of the conductive layer 10. For example, if the shape of the conductive layer 10 is a frustum of pyramid or a prism, the shape of the cross section of the second protective layer 13 is a parallelogram. If the shape of the conductive layer 10 is a truncated cone or a cylinder, the cross section of the second protective layer 13 has a rectangular shape. The present disclosure shall not be limited to the embodiments shown or described herein.

Optionally, the second protective layer 13 has a thickness of about 5 to 50 nanometers. The thin film transistor provided by the embodiment of the present disclosure may include: a gate electrode and a source/drain electrode, wherein the gate electrode and/or the source/drain electrode are electrodes including a protective layer and a conductive layer, and the protective layer includes a first protective layer disposed on a surface of the conductive layer and a second protective layer disposed on a side face of the conductive layer, the second protective layer being used to isolate the conductive layer from the outside. The second protective layer can be used to block oxygen and/or hydrogen. By providing the second protective layer on the side face of the conductive layer of the electrode, hydrogen can be prevented from entering the conductive layer or its interface, and a metal/metal-oxide interface (for example, an aluminum/alumina interface) can be avoided due to oxidation of the conductive layer, thereby avoiding hydrogen entering such an interface. Thus, the uneven contact resistance or breakage of the electrode due to hydrogen can be avoided, and the crack of the protective film can be avoided, thereby improving the conductivity of the conductor such as the electrodes in the device, and improving the yield and reliability of the device.

FIG. 4 is a schematic structural diagram of an electrode according to some embodiments of the present disclosure; FIG. 5 is a schematic structural diagram of a thin film transistor according to some embodiments of the present disclosure. As shown in FIGS. 4 and 5, the thin film transistor includes a gate electrode 23 and source/drain electrodes 25. The gate electrode 23 and/or the source/drain electrode 25 are electrodes including a protective layer and a conductive layer 10, which include: a first protective layer disposed on a surface of the conductive layer 10 and a second protective layer 13 disposed on a side face of the conductive layer 10, wherein the second protective layer 13 is used to isolate the conductive layer from the outside (for example, external silicon oxide or the like). In some embodiments, the materials of the first protective layer and the second protective layer are different. In some embodiments, the second protective layer is used to block oxygen and/or hydrogen.

In the present embodiment, the thin film transistor further includes an active layer 21, a gate insulating layer 22, an interlayer insulating layer 24, and a passivation layer 26 which are disposed on the substrate 20. It should be noted that the structure of the thin film transistor may be a top gate structure or a bottom gate structure. FIG. 5 is an example in which the top gate structure is taken as an example. In addition, FIG. 5 also illustrates an example in which the gate electrode and the source and drain electrodes are all electrodes provided by the embodiments of the present disclosure.

In a specific implementation, the first protective layer includes: a first metal layer 11 disposed on the lower surface of the conductive layer 10, which is adjacent to the substrate 20, and a second metal layer 12 disposed on the upper surface of the conductive layer 10, which faces away from the substrate 20. It is to be understood that the orthographic projection of the first metal layer 11 on the substrate 20 is greater than or equal to the orthographic projection of the conductive layer 10 on the substrate 20, and the orthographic projection of the conductive layer 10 on the substrate 20 is greater than or equal to the orthographic projection of the second metal layer 12 on the substrate 20. The conductive layer 10 may have a prismatic or prismatic shape, or may also have a shape of truncated cone or cylindrical shape. The shapes of the first metal layer 11 and the second metal layer 12 are the same as the shape of the conductive layer 10, and embodiments of the present disclosure are not intended to be limited to the embodiments shown or described herein.

The second protective layer 13 is disposed on the side faces of the first metal layer 11, the conductive layer 10, and the second metal layer 12. The height h of the second protective layer 13 is equal to the sum of the thicknesses of the first metal layer 11, the conductive layer 10, and the second metal layer 12.

Optionally, materials of the first metal layer 11 and the second metal layer 12 comprise, but are not limited to, molybdenum. It should be noted that the first metal layer 11 and the second metal layer 12 not only can be electrically conductive, but also can protect the conductive layer 10 from being oxidized.

The conductive layer 10 may be formed of metal material. Optionally, the material of the conductive layer 10 comprises: aluminum.

Optionally, the material of the second protective layer 13 comprises: aluminum nitride. It should be noted that the second protective layer 13 may also be other materials whose hydrogen permeability is weak, and the disclosure is not limited to the embodiments shown or described herein.

In a specific implementation, the shape of the second protective layer 13 is related to the shape of the conductive layer. For example, if the shape of the conductive layer is a prism or a prism, the shape of the cross section of the second protective layer 13 is a parallelogram. If the shape of the conductive layer is a truncated cone or a cylinder, the cross section of the second protective layer 13 has a rectangular shape. The present disclosure is not limited to the embodiments shown or described herein.

Optionally, the second protective layer 13 has a thickness of about 5 to 50 nanometers.

According to the embodiment of the present disclosure, a thin film transistor comprises: a gate electrode and a source/drain electrode, the gate electrode and/or the source/drain electrode are/is electrode(s) including a protective layer and a conductive layer, wherein the protective layer includes a first protective layer disposed on a surface of the conductive layer and a second protective layer disposed on a side face of the conductive layer. The second protective layer is used to block oxygen and/or hydrogen. By providing the second protective layer on the side face of the conductive layer of the electrode, it is possible to avoid uneven contact resistance of, or even breakage of, the electrode due to hydrogen “walking” and entering the conductive layer, and cracking of the protective film, etc., thereby improving the conductivity of the conductor in the device such as the electrodes, and improving the yield and reliability of the device.

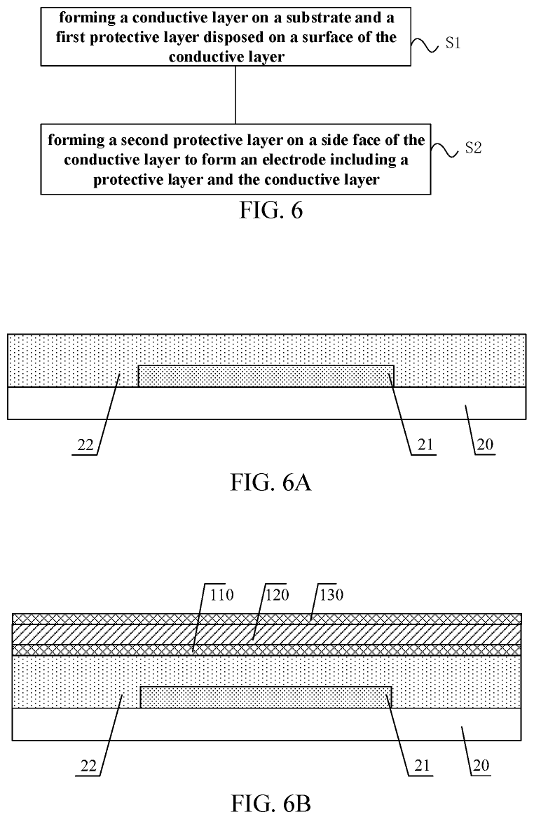

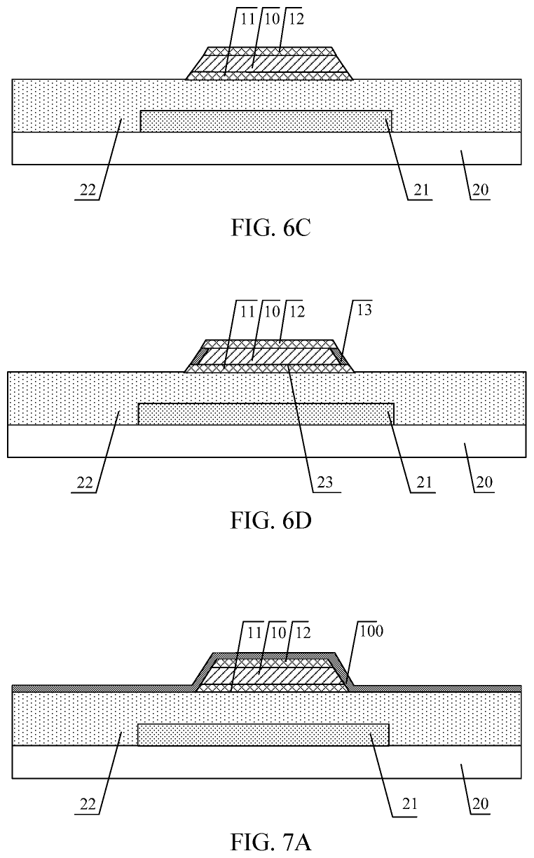

According to some embodiments of the present disclosure, a method of fabricating a thin film transistor is provided. FIG. 6 is a flow chart of a method of fabricating a thin film transistor according to some embodiments of the present disclosure. As shown in FIG. 6, the manufacturing method specifically includes the following steps.

Step S1, forming a conductive layer on a substrate and a first protective layer disposed on a surface of the conductive layer.

In a specific implementation, step S1 specifically includes following steps.
At Step S11, a stack of a first metal film, a conductive thin film and a second metal film is sequentially formed (for example, deposited) on the substrate.
In a specific implementation, the first metal film, the conductive film, and the second metal film may be deposited by a chemical vapor deposition (CVD) process, an evaporation process, or a sputtering process.
Optionally, the materials of the first metal film and the second metal film each are, for example, molybdenum. The conductive film may be formed of metal material such as aluminum.
At Step S12, a first metal layer, a conductive layer and a second metal layer are formed by a patterning process. In other words, the stack can be patterned to form a first metal layer, a conductive layer, and a second metal layer corresponding to the respective films in the stack.
The patterning process may include: photoresist coating, exposure, development, etching, photoresist stripping, etc. The first protective layer includes: the first metal layer and the second metal layer.

It is to be understood that the orthographic projection of the first metal layer on the substrate is greater than or equal to the orthographic projection of the conductive layer on the substrate, and the orthographic projection of the conductive layer on the substrate is greater than or equal to the orthographic projection of the second metal layer on the substrate. The shape of the conductive layer may be a prismatic or prismatic shape, or may also be a truncated cone or a cylindrical shape. The shapes of the first metal layer and the second metal layer are the same as the shape of the conductive layer. Embodiments of the present disclosure shall not be limited to the embodiments shown or described herein.

Step S2, forming a second protective layer on a side face of the conductive layer to form an electrode including a protective layer and a conductive layer.

The protective layer comprises: the first protective layer and the second protective layer, wherein the second protective layer is used to isolate the conductive layer from the outside, for example, the conductive layer is prevented from being in contact with silicon oxide.

In a specific implementation, step S2 specifically includes: treating the conductive layer with nitrogen plasma to form the second protective layer disposed on the side face of the conductive layer.

In some embodiments, the material of the second protective layer is aluminum nitride. The second protective layer may have a thickness of 5 to 50 nm. It should be noted that the thickness of the second protective layer can be controlled by the content of nitrogen. The present disclosure is not limited to the embodiments shown or described herein.

According to the embodiment, the fabrication process is simplified by using nitrogen plasma treatment, the mask that is otherwise needed is avoided, the complexity of the fabrication process is reduced, and the fabrication process of the thin film transistor is simplified.

In this embodiment, the electrode may be gate electrode and/or source/drain electrode.

According to the embodiment of the present disclosure, a method for fabricating a thin film transistor is provided that comprises: forming a conductive layer on a substrate and a first protective layer disposed on a surface of the conductive layer, and forming a second protective layer on a side face of the conductive layer, so that an electrode is formed to include a protective layer and the conductive layer, wherein the protective layer comprises: the first protective layer and the second protective layer, and the second protective layer is used to isolate the conductive layer from the outside. The second protective layer can be used to block oxygen and/or hydrogen. By providing the second protective layer on the side face of the conductive layer of the electrode, it is possible to avoid uneven contact resistance of or even breakage of the electrode due to hydrogen “walking” and entering the conductive layer, and to avoid cracking of the protective film, thereby improving the conductivity of the conductor such as electrode etc. in the device, and improving the yield and reliability of the device.

Next, a method of fabricating a thin film transistor according to some embodiments of the present disclosure will be further specifically described with reference to FIGS. 6A-6D by taking a thin film transistor of a top gate structure in which the gate electrode and the source/drain electrode both including a conductive layer and a protective layer as an example. Patterning process includes: photoresist coating, exposure, development, etching, photoresist stripping, and the like.

At Step 101, an active layer 21 and a gate insulating layer 22 are formed on the substrate 20, as shown in FIG. 6A.

In a specific implementation, the material of the substrate 20 may be, for example, glass or plastic. In the embodiment of the present disclosure, there is no any particular limitation on the substrate, and those skilled in the art can select the substrate as needed. Further, the substrate 20 may be subjected to a pre-cleaning process before the active layer 21 is formed.

In a specific implementation, the material of the active layer 21 is polysilicon. The present disclosure however is not limited thereto. The active layer 21 may be formed of any suitable semiconductor material such as, but not limited to, silicon, an oxide semiconductor such as IGZO, or the like.

Optionally, the material of the gate insulating layer 22 may be silicon oxide and/or silicon nitride.

At Step 102, a first metal film 110, a conductive film 120, and a second metal film 130 are deposited on the substrate 20 on which the active layer 21 and the gate insulating layer 22 are formed, as shown in FIG. 6B.

In a specific implementation, the first metal film 110, the conductive film 120, and the second metal film 130 are deposited by a CVD process, an evaporation process, or a sputtering process.

The material of the first metal film 110 and the second metal film 130 is molybdenum, and the material of the conductive film 120 is aluminum.

At Step 103, the first metal film 110, the conductive film 120, and the second metal film 130 are processed by a patterning process to form a first metal layer 11, a conductive layer 10, and a second metal layer 12, as shown in FIG. 6C.

The first protective layer includes the first metal layer 11 and the second metal layer 12.

At Step 104, the conductive layer 10 is treated with nitrogen plasma to form a second protective layer 13 disposed on the side face of the conductive layer 10 to form a gate electrode 23 including a protective layer and the conductive layer, as shown in FIG. 6D.

The protective layer includes the first metal layer 11, the second metal layer 12, and the second protective layer 13.

At Step 105, an interlayer insulating layer 24, a source/drain electrode 25, and a passivation layer 26 are formed on the substrate 20, as shown in FIG. 3.

The material of the interlayer insulating layer 24 and the passivation layer 26 is silicon oxide.

In a specific implementation, the source-drain electrode(s) 25 is/are formed by the processes of steps 102-104, and are not repeatedly described herein.

According to some embodiments of the present disclosure, a method for fabricating a thin film transistor is provided that specifically includes the following steps.

Step S1, forming a conductive layer on the substrate and a first protective layer disposed on the surface of the conductive layer.

In a specific implementation, step S1 specifically includes following steps.
Step S11, depositing a first metal film, a conductive thin film and a second metal film on the substrate in order. In a specific implementation, the first metal film, the conductive film, and the second metal film are deposited by a chemical vapor deposition (CVD) process, an evaporation process, or a sputtering process.
Optionally, the materials of the first metal film and the second metal film are both molybdenum, and the material of the conductive film is aluminum.
Step S12, forming a first metal layer, a conductive layer and a second metal layer by a patterning process. The patterning process includes: photoresist coating, exposure, development, etching, photoresist stripping, etc. The first protective layer includes: the first metal layer and the second metal layer.

It is to be understood that the orthographic projection of the first metal layer on the substrate is greater than or equal to the orthographic projection of the conductive layer on the substrate, and the orthographic projection of the conductive layer on the substrate is greater than or equal to the orthographic projection of the second metal layer on the substrate. The shape of the conductive layer may be a prismatic or prismatic shape, or may also be a truncated cone shape or a cylindrical shape. The shapes of the first metal layer and the second metal layer are the same as the shape of the conductive layer. Embodiments of the present disclosure shall not be limited to the embodiments shown or described herein.

Step S2, forming a second protective layer on a side face of the conductive layer to form an electrode including a protective layer and the conductive layer.

The protective layer comprises the first protective layer and the second protective layer, wherein the second protective layer is used to isolate the conductive layer from the outside.

In a specific implementation, step S2 specifically includes following steps.
Step S21, depositing a protective material film on the substrate on which the first metal layer, the conductive layer and the second metal layer are formed. In a specific implementation, the protective material film is deposited by a chemical vapor deposition (CVD) process, an evaporation process, a sputtering process, or the like. The material of the protective material film may be aluminum nitride. The thickness of the protective material film may be 5 to 50 nm.
Step S22, forming a second protective layer on the side faces of the first metal layer, the conductive layer and the second metal layer by a patterning process.

In this embodiment, the electrode comprises gate electrode and/or source/drain electrode(s).

According to the embodiment of the present disclosure, a method for fabricating a thin film transistor is provide that comprises: forming a conductive layer on a substrate and a first protective layer disposed on a surface of the conductive layer, and forming a second protective layer on a side face of the conductive layer, so that an electrode includes a protective layer and the conductive layer is formed, wherein the protective layer comprises: the first protective layer and the second protective layer, and the second protective layer is used to isolate the conductive layer from the outside. The second protective layer can be used to block oxygen and/or hydrogen. By providing a second protective layer that blocks oxygen on the side face of the conductive layer of the electrode, uneven contact resistance of or even fracture of the electrode and cracking of the protective film, etc. due to hydrogen “going around” and entering the conductive layer can be avoided. Thus, the conductivity of the conductors such as electrodes in the device is improved, and the yield and reliability of the device are improved.

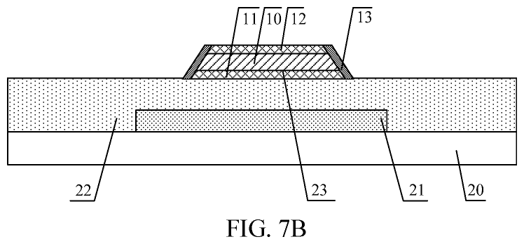

Next, a method of fabricating a thin film transistor according to some embodiments of the present disclosure will be further specifically described with reference to FIGS. 7A-7B by taking a thin film transistor of a top gate structure in which the gate electrode and the source/drain electrode(s) both include a conductive layer and a protective layer an example. The patterning process includes: photoresist coating, exposure, development, etching, photoresist stripping, etc.

At Step 201, forming an active layer 21 and a gate insulating layer 22 on the substrate 20, depositing a first metal film, a conductive thin film and a second metal film on the substrate 20 on which the active layer 21 and the gate insulating layer 22 are formed, processing the first metal film, the conductive film, and the second metal film by a patterning process to form a first metal layer 11, a conductive layer 10, and a second metal layer 12.

In a specific implementation, for the step 201 in this embodiment, the steps 101-103 according to the embodiments of the present disclosure can be referred to, and the step 201 thus is not described in detail herein.

At Step 202, depositing a protective material film 100 on the substrate 20 on which the first metal layer 11, the conductive layer 10 and the second metal layer 12 are formed, as shown in FIG. 7A. The protective material film covers at least the second metal layer and the side faces of the first metal layer, the conductive layer, and the second metal layer.

In an implementation, the material of the protective material film 100 is aluminum nitride, and the thickness of the protective material film 100 is 5-50 nm.

At Step 203, processing the protective material film 100 by a patterning process to form a second protective layer 13 disposed on the sides of the first metal layer 11, the conductive layer 10, and the second metal layer 12, so that a gate electrode 23 including a conductive layer and the protective layer is formed, as shown in FIG. 7B. In an embodiment, the portion of the protective material film on the sides of the first metal layer, the conductive layer, and the second metal layer may be retained by a patterning process to remove undesired portions of the protective material film. Thereby, the first metal layer 11, the conductive layer 10, and the second metal layer 12 are formed.

The protective layer includes the first metal layer 11, the second metal layer 12, and the second protective layer 13.

At Step 204, forming an interlayer insulating layer 24, a source/drain electrode 25, and a passivation layer 26 on the substrate 20, as shown in FIG. 5.

In an implementation, the material of the interlayer insulating layer 24 and the passivation layer 26 is silicon oxide.

In a specific implementation, the source/drain electrode(s) 25 is/are formed by the processes of steps 201-203, and are not repeatedly described herein.

It should be understood that the principles of the embodiments of the present disclosure can be applied to a wide variety of devices comprising, but not limited to, active devices such as transistors, and passive devices, such as bonding lines or wiring. In addition, although the description has been made here with an example in which an electrode is used as a conductor, it is obvious that the disclosure shall not be limited thereto. For example, in other embodiments, the principles of the embodiments of the present disclosure may be likewise or adaptably applied to the conductors such as wiring, pads, and the like.

According to some embodiments of the present disclosure, an array substrate is provided that includes the aforementioned device such as the thin film transistor.

The device in this embodiment can adopt the device provided according to the above embodiments. The principles and effects thereof are similar and will not be repeatedly described here.

Based on the same inventive concept, a display device including an array substrate is provided according to some embodiments of the present disclosure provide.

The display device includes a display panel, and the display panel includes an array substrate, and the array substrate comprises the array substrate provided by the embodiments of the present disclosure. The principles and effects are similar, and will not be repeatedly described here.

In a specific implementation, the display device may be a liquid crystal display panel, an organic light-emitting diode (OLED) display panel, an electronic paper, a mobile phone, a tablet computer, a television set, a display, a notebook computer, a digital photo frame, a navigation device, or any product or component that has a display function. The embodiments of the present disclosure shall not be limited thereto.

The embodiments of the present disclosure as above described are merely used to facilitate the understanding of the present disclosure, and are not intended to limit the scope of the present disclosure. Modifications or variations in the form and details of the implementations can be made by those skilled in the art without departing from the spirit and scope of the disclosure. The scopes of the inventions shall be only defined by the appended claims.

The present application claims priority to the Chinese Application No. 201710769888.9 filed on Aug. 30, 2017 and the Chinese Application No. 201721104937.9 filed on Aug. 30, 2017, which are herein incorporated in its entirety by reference.

1. An electrode structure comprising:
a protective layer and a conductive layer;
wherein the protective layer comprises: a first protective layer disposed on a surface of the conductive layer, and a second protective layer disposed on a side face of the conductive layer for isolating the conductive layer from the outside.

2. The electrode structure according to claim 1, wherein
materials of the first protective layer and the second protective layer are different, and
the second protective layer is configured to block oxygen and/or hydrogen.

3. The electrode structure according to claim 1, wherein the first protective layer comprises a first metal layer and a second metal layer, the first metal layer being disposed on a side of the conductive layer adjacent to a substrate, the second metal layer is disposed on a side of the conductive layer facing away from the substrate.

4. The electrode structure according to claim 3, wherein the second protective layer is configured to cover the side face of the conductive layer.

5. The electrode structure of claim 3, wherein the second protective layer is configured to completely cover the side face of the conductive layer.

6. The electrode structure according to claim 3, wherein the second protective layer is configured to cover sides of the first metal layer, the conductive layer, and the second metal layer.

7. The electrode structure according to claim 3, wherein materials of the first metal layer and the second metal layer comprise: molybdenum.

8. The electrode structure according to claim 3, wherein materials of the first metal layer and the second metal layer are different.

9. The electrode structure claim 1, wherein material of the conductive layer comprises aluminum, and material of the second protective layer comprises aluminum nitride.

10. The electrode structure according to claim 1, wherein the second protective layer has a thickness of 5 to 50 nm.

11. The electrode structure of claim 1, wherein the conductive layer comprises a metal material.

12. A thin film transistor comprising an electrode structure according to claim 1, wherein at least one of the following comprises the electrode structure: gate electrode, source electrode, drain electrode, or wiring of the thin film transistor.

13. An array substrate comprising the thin film transistor of claim 12.

14. A method for fabricating an electrode structure, comprising:
forming a conductive layer on a substrate and a first protective layer for the conductive layer; and
forming a second protective layer covering at least a side of the conductive layer for isolating the conductive layer from the outside.

15. The method of claim 14, wherein
materials of the first protective layer and the second protective layer are different,
the second protective layer is configured to block oxygen and/or hydrogen.

16. The method of claim 14, wherein forming the conductive layer on the substrate and the first protective layer on a surface of the conductive layer comprises:
forming a stack of a first metal film, a conductive film, and a second metal film on the substrate;
patterning the stack to form a first metal layer, the conductive layer, and a second metal layer,
wherein the first protective layer comprises the first metal layer and the second metal layer.

17. The method of claim 16, wherein forming the second protective layer comprises:
processing the conductive layer with nitrogen plasma to form the second protective layer.

18. The method of claim 16, wherein forming the second protective layer comprises:
depositing a protective material film on the substrate on which the first metal layer, the conductive layer and the second metal layer are formed, the protective material film covering at least the second metal layer and sides of the first metal layer, the conductive layer and the second metal layer; and
patterning the protective material film by a patterning process so that a portion of the protective material film which is on the sides of the first metal layer, the conductive layer, and the second metal layer is remained to form the second protective layer.

19. The method of claim 14, wherein at least one of the following comprises the electrode structure: a gate electrode, a source electrode, a drain electrode, or a wiring of a thin film transistor.

20. The method of claim 16, wherein the conductive film is formed of metal material.
